(19) United States
(12) Patent Application Publication
(10) Pub. No.: US 2026/0071980 A1
(43) Pub. Date: Mar. 12, 2026

(54) METHOD OF INSPECTING A SEMICONDUCTOR DEVICE AND METHOD OF MANUFACTURING A SEMICONDUCTOR DEVICE INCLUDING THE SAME

(71) Applicant: Samsung Electronics Co., Ltd., Suwon-si (KR)

(72) Inventors: Dongeun Kim, Suwon-si (KR); Jinwoo Lee, Suwon-si (KR); Su-Young Lee, Suwon-si (KR)

(21) Appl. No.: 19/035,375

(22) Filed: Jan. 23, 2025

(30) Foreign Application Priority Data
Sep. 10, 2024 (KR) 10-2024-0123431

(51) Int. Cl. G01N 23/2251; H01L 21/66

(52) U.S. Cl. CPC G01N 23/2251; H10P 74/203; G01N 2223/6116

(57) ABSTRACT

A method of inspecting a semiconductor device includes obtaining a brightness of a scanning electron microscope (SEM) image according to an intensity of a current incident on a normal target, selecting an optimal current range for inspecting a target, based on the brightness of the SEM image according to the intensity of the current, and inspecting the target, based on a current having the optimal current range, wherein the selecting of the optimal current range for inspecting the target includes dividing the brightness of the SEM image according to the intensity of the current into a first area, a second area and a third area, based on the intensity of the current incident on the target.

### CROSS-REFERENCE TO RELATED APPLICATION

This application is based on and claims priority under 35 U.S.C. § 119 to Korean Patent Application No. 10-2024-0123431, filed on Sep. 10, 2024, in the Korean Intellectual Property Office, the disclosure of which is incorporated by reference herein in its entirety.

### BACKGROUND

The inventive concept relates to a method of inspecting a semiconductor device and a method of manufacturing the semiconductor device including the same, and more specifically, to a method of inspecting a semiconductor device by using a scanning electron microscope (SEM) image and a method of manufacturing the semiconductor device including the same.

Semiconductor devices may be manufactured through various processes. For example, semiconductor devices may be manufactured through a photo process, an etching process, a deposition process, and a test process on wafers such as silicon. In a test process for a semiconductor device, an electrical defect in the semiconductor device may be measured. Whether the semiconductor device has an electrical defect may be confirmed by scanning the semiconductor device into which electrons have been injected. To this end, a SEM may be used.

### SUMMARY

The inventive concept provides a method of inspecting a semiconductor device with increased reliability and a method of manufacturing the semiconductor device manufacturing method including the same.

In addition, the problems to be solved by the technical idea of the inventive concept are not limited to the problems mentioned above, and other problems may be clearly understood by one of ordinary skill in the art from the description below.

According to an aspect of the inventive concept, there is provided a method of inspecting a semiconductor device including searching for a target in the semiconductor device, obtaining brightness of a scanning electron microscope (SEM) image according to an intensity of a current incident on a normal target, determining an optimal current range for inspecting the target, based on the brightness of the SEM image according to the intensity of the current, and inspecting the target based on a current having the optimal current range, wherein the determining of the optimal current range for inspecting the target includes dividing the brightness of the SEM image according to the intensity of the current into a first area, a second area, and a third area based on the intensity of the current incident on the target, wherein the first area is an area in which the current incident on the target is much lower than a critical current, wherein the second area is an area in which the current incident on the target is similar to the critical current, wherein the third area is an area in which the current incident on the target is much greater than the critical current, and wherein the critical current is a current corresponding to a point at which curvature of a brightness graph of the SEM image greatly changes according to the intensity of the current.

According to another aspect of the inventive concept, there is provided a method of inspecting a semiconductor device including searching for a target in the semiconductor device, obtaining brightness of a SEM image according to an intensity of a current incident on a normal target, determining a time constant of the target and an optimal current range for inspecting the target, based on the brightness of the SEM image according to the intensity of the current, and inspecting the target based on a current having the optimal current range, wherein the determining of the time constant of the target and the optimal current range for inspecting the target includes modeling the target as a resistor-capacitor (RC) circuit including a resistor and a capacitor, calculating the time constant of the target, and selecting the optimal current range for inspecting the target, and wherein the determining of the time constant of the target and the optimal current range for inspecting the target is performed by treating a current incident on the target as a discrete electron train including movement of individual electrons.

According to another aspect of the inventive concept, there is provided a method of manufacturing a semiconductor device including preparing a wafer, manufacturing the semiconductor device by performing a semiconductor process on the wafer, inspecting the semiconductor device, and performing a subsequent process with respect to the semiconductor device, wherein the inspecting of the semiconductor device includes searching for the target in the semiconductor device, obtaining brightness of a SEM image according to an intensity of a current incident on the target, selecting an optimal current range for inspecting the target, based on the brightness of the SEM image according to the intensity of the current, and inspecting the target based on a current having the optimal current range, wherein the selecting of the optimal current range for inspecting the target includes dividing the brightness of the SEM image according to the intensity of the current into a first area, a second area, and a third area based on the intensity of the current incident on the target, wherein the first area is an area in which the current incident on the target is much lower than a critical current, wherein the second area is an area in which the current incident on the target is similar to the critical current, wherein the third area is an area in which the current incident on the target is much greater than the critical current, and wherein the critical current is a current corresponding to a point at which curvature of a brightness graph of the SEM image greatly changes according to the intensity of the current.

### BRIEF DESCRIPTION OF THE DRAWINGS

Embodiments will be more clearly understood from the following detailed description taken in conjunction with the accompanying drawings in which:

FIG. 1 is a flowchart illustrating a method of inspecting a semiconductor device, according to an example embodiment;

FIG. 2 is a diagram illustrating an apparatus for inspecting a semiconductor device, according to an example embodiment;

FIG. 3 is a plan view illustrating a target disposed in a semiconductor device, according to an example embodiment;

FIG. 4 is a flowchart illustrating a method of calculating a time constant of a target and determining the optimal current range for inspecting the target, according to an example embodiment;

FIG. 5 is a diagram illustrating a target modeled as a resistor-capacitor (RC) circuit including a resistor and a capacitor, according to an example embodiment;

FIG. 6 is a graph illustrating brightness of an obtained SEM image according to an intensity of a current incident on a target, according to an example embodiment;

FIG. 7 is a graph illustrating a current incident on a target, according to an example embodiment;

FIG. 8 is a graph illustrating a surface voltage of a semiconductor device generated by a current incident on a target, according to an example embodiment;

FIG. 9 is a graph illustrating the intensity of brightness of an SEM image according to a current incident on a plurality of targets, according to an example embodiment; and

FIG. 10 is a flowchart illustrating a method of manufacturing a semiconductor device, including a method of inspecting the semiconductor device, according to an example embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted. In the following drawings, the thickness or size of each layer is exaggerated for convenience and clarity of explanation, and accordingly, may be slightly different from the actual shape and ratio.

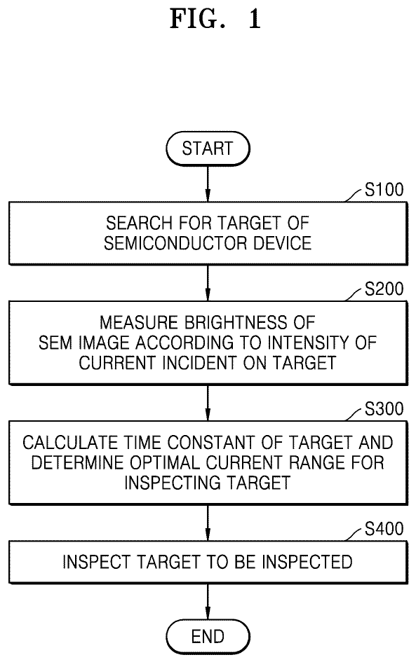

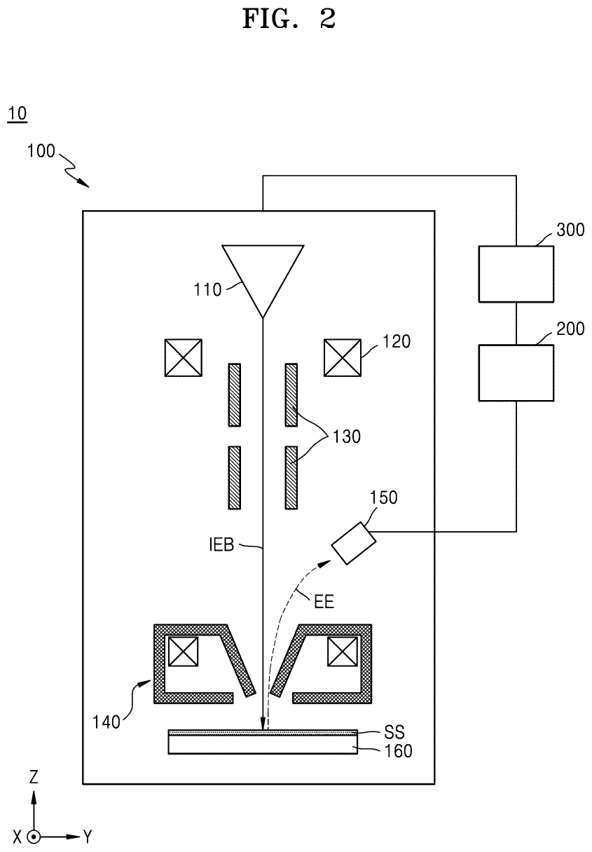

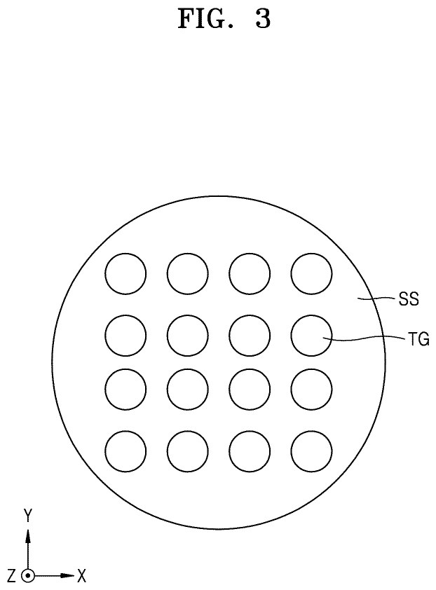

FIG. 1 is a flowchart illustrating a method of inspecting a semiconductor device SS according to an example embodiment. FIG. 2 is a diagram illustrating an apparatus for inspecting the semiconductor device SS according to an example embodiment. FIG. 3 is a plan view illustrating a target TG disposed in the semiconductor device SS according to an example embodiment.

Referring to FIGS. 1 to 3, first, the target TG of the semiconductor device SS may be searched for (S100). Here, the semiconductor device SS may be a device in which a pattern is formed on a substrate such as a wafer. In an embodiment, the semiconductor device SS may include an electrical path formed on a substrate. For example, the semiconductor device SS may include a memory device. However, the embodiment is not limited thereto, and various types of semiconductor devices SS may be an inspection object.

The semiconductor device SS may include a plurality of targets TG. The target TG may be an area in which an electrical path is formed on the semiconductor device SS. In an embodiment, an area in which at least a part of an electrical path formed on the semiconductor device SS is exposed may be the target TG. The target TG may be an inspection object of the method of inspecting the semiconductor device SS. In an embodiment, a pre-scan may be performed on the semiconductor device SS so that the target TG may be searched for. In another embodiment, the target TG may be searched for based on graphical data of the semiconductor device SS. Herein, inspecting the semiconductor device SS may include inspecting at least one of the one or more targets TG of the semiconductor device SS.

In addition, the target TG may include various types of structures. For example, in a memory semiconductor device, a structure may include a gate bit line and/or a gate body serial contact. Operations S200 to S400, which will be described below, may be compared and inspected between the targets TG of the same type.

In an embodiment, the target TG may be inspected by irradiating an electron beam to the semiconductor device SS by using a scanning electron microscope (SEM). FIG. 2 illustrates that the target TG is inspected by irradiating the electron beam to the semiconductor device SS by using the SEM, but the embodiment is not limited thereto. Various types of apparatuses for inspecting the semiconductor device SS may be used.

An apparatus 10 for inspecting the semiconductor device SS may be configured to inspect the semiconductor device SS. The apparatus 10 for inspecting the semiconductor device SS may include a SEM 100, a controller 200, and a processor 300.

The SEM 100 may be configured to measure the semiconductor device SS. In an embodiment, the SEM 100 may measure the semiconductor device SS in a scanning method. The SEM 100 may obtain an SEM image by measuring the semiconductor device SS.

In an embodiment, the SEM 100 may measure the semiconductor device SS by irradiating an input electron beam IEB to the semiconductor device SS and detecting emission electrons EE emitted from the semiconductor device SS by an interaction between the input electron beam IEB and the semiconductor device SS. The emission electrons EE may be generated by elastic scattering or may be generated by inelastic scattering.

Elastic scattering is a phenomenon in which electrons included in the input electron beam IEB are directed in the opposite direction to an input direction of the input electron beam IEB, without substantial change in the energy of electrons included in the input electron beam IEB, by the voltage of atomic nuclei constituting the semiconductor device SS. Electrons escaping from a surface of the semiconductor device SS by elastic scattering are referred to as backscattering electrons, and the backscattering electrons may have energy of about 50 eV or more. The backscattering electrons may include information about a structure in the vicinity of the surface of the semiconductor device SS and information about a composition.

Inelastic scattering is a phenomenon in which electrons included in atoms in the semiconductor device SS are emitted by interaction between atoms with electrons on an electron orbit in the semiconductor device SS when the electrons included in the input electron beam IEB are incident on the surface of the semiconductor device SS. A secondary electron, an auger electron, and an X-ray may be emitted by inelastic scattering. Secondary electrons among the emission electrons EE may have energy of about several eV. The secondary electrons may include information about irregularities in the vicinity of a surface of each of the semiconductor devices SS.

In the secondary electrons, electrons bound to atoms in the semiconductor device SS are emitted as free electrons by transferring energy to the electrons due to electrons included in the input electron beam IEB. When electrons at a low energy level other than a valence band are emitted as the secondary electrons, electrons at a high energy level may move to the low energy level and emit the X-ray, and electrons excited by the X-ray and emitted from a wafer may be auger electrons. The X-ray may include a continuum X-ray and a characteristic X-ray. The auger electron and the X-ray may include information about a composition and chemical bonding in the vicinity of a surface of the wafer.

In addition, the SEM 100 may further detect a signal due to incoherent elastic scattering electrons, transmitted electrons, and cathodoluminescence.

The SEM 100 may include an electron gun 110, a condenser lens 120, a deflector 130, an objective lens 140, a detector 150, and a stage 160.

The electron gun 110 may generate and emit the input electron beam IEB. A wavelength of the input electron beam IEB may be determined by energy of electrons emitted from the electron gun 110. In an embodiment, the wavelength of the input electron beam IEB may be several nm. For example, the electronic gun 110 may be any one of a cold field emission (CFE) type, a Schottky emission (SE) type, and a thermionic emission (TE) type.

The electron gun 110 may generate the input electron beam IEB by thermally or electrically applying energy above a work function (i.e., a difference value between an energy level and Fermi energy in vacuum) to electrons included in a solid material which is an electron source.

The condenser lens 120 may be disposed on a path of the input electron beam IEB between the electron gun 110 and the semiconductor device SS. According to some embodiments, the condenser lens 120 may focus the input electron beam IEB on the deflector 130. Accordingly, controllability of the input electron beam IEB by the deflector 130 may be improved.

The deflector 130 may be disposed on a path of the input electron beam IEB between the condenser lens 120 and the semiconductor device SS. The deflector 130 may deflect the input electron beam IIB emitted from the electron gun 110. The deflector 130 may deflect the input electron beam IEB so that the input electron beam IEB passes through the condenser lens 120 and the objective lens 140 and is irradiated to a set location on the semiconductor device SS. According to some embodiments, the deflector 130 may scan the input electron beam IEB on the semiconductor device SS. The deflector 130 may be either an electric type or a magnetic type.

The objective lens 140 may be disposed on a path of the input electron beam IEB between the deflector 130 and the semiconductor device SS. The objective lens 140 may focus the input electron beam IEB on the semiconductor device SS. As the input electron beam IEB is limited to a narrow area on the semiconductor device SS, the resolution of the SEM 100 may be further improved.

In the above, a transmission system of the input electron beam IEB including the condenser lens 120, the deflector 130, and the objective lens 140 has been described, but this is a non-limiting example and does not limit the technical idea of the inventive concept. One of ordinary skill in the art will be able to easily reach the transmission system of the input electron beam IEB including additional focusing lenses and an additional deflector based on the description given herein.

The detector 150 may detect at least some of the emission electrons EE reflected from the semiconductor device SS. For example, the detector 150 may detect secondary electrons and/or backscattering particles emitted from the semiconductor device SS. In addition, the detector 150 may generate an SEM image by detecting the emission electrons EE.

The stage 160 may support the semiconductor device SS which is a measurement object. The stage 160 may move the semiconductor device SS in a horizontal direction (X direction and/or Y direction) and/or a vertical direction (Z direction) or rotate the semiconductor device SS in the vertical direction (Z direction) so that the semiconductor device SS is aligned with an optical system (i.e., an optical system including the electron gun 110, the condenser lens 120, the deflector 130, and the objective lens 140) that transmits the input electron beam IEB.

Herein, a direction parallel to an upper surface of the stage 160 is defined as the horizontal direction (X direction and/or Y direction), and a direction perpendicular to the horizontal direction (X direction and/or Y direction) is defined as the vertical direction (Z direction).

The controller 200 may be configured to control an operation of the SEM 100. In an embodiment, the controller 200 may control the electron gun 110 to change a current of the input electron beam IEB incident on the semiconductor device SS. The controller 200 may control the electronic gun 110 so that the semiconductor device SS may be inspected in the optimal current range calculated by the processor 300.

The processor 300 may perform an operation on one or more SEM images generated by the detector 150. As will be described in detail below, the processor 300 may measure brightness of a SEM image. In addition, the processor 300 may measure a time constant of the semiconductor device SS based on the brightness of the SEM image. In addition, the processor 300 may determine the optimal current range for performing semiconductor device inspection based on the brightness of the SEM image. The processor 300 may determine a defective target TG based on the brightness of the SEM image. For example, the processor 300 may calculate the critical current and select, as the optimal current range, a range of currents in which the intensity of the current incident on the target TG is much greater than the critical current.

The controller 200 and the processor 300 may be implemented in hardware, firmware, software, or any combination thereof. For example, the controller 200 and the processor 300 may be computing devices such as a workstation computer, a desktop computer, a laptop computer, or a tablet computer. For example, the controller 200 and the processor 300 may include memory devices such as Read Only Memory (ROM) and Random Access Memory (RAM), and processors configured to perform certain operations and algorithms, such as a microprocessor, a central processing unit (CPU), and a graphics processing unit (GPU). In addition, the controller 200 and the processor 300 may include a receiver and a transmitter for receiving and transmitting electrical signals.

After the target TG of the semiconductor device SS is searched for (S100), the brightness of the SEM image according to the intensity of the current incident on the target TG may be measured (S200). Operation S200 may be performed by measuring the brightness of the SEM image while changing the intensity of the current incident on the semiconductor device SS. The controller 200 may control the electron gun 110 to change the intensity of the current of the input electron beam IEB incident on the target TG. In an embodiment, the brightness of the SEM image may be measured based on the number of emission electrons EE detected by the detector 150. In an embodiment, as the number of emission electrons EE detected by the detector 150 increases, the brightness of the SEM image may increase. On the contrary, as the number of emission electrons EE detected by the detector 150 decreases, the brightness of the SEM image may decrease. That is, the number of emission electrons EE (or the intensity of the emitted current) detected by the detector 150 may be measured based on the brightness of the SEM image. In an embodiment, the brightness of the SEM image may be expressed in a gray scale.

The SEM image may include an area corresponding to the target TG and an area corresponding to the background. Herein, the brightness of the SEM image may be the brightness of the SEM image corresponding to the area of the target TG.

After obtaining brightness data of the SEM image according to the intensity of the current incident on the target TG (S200), the time constant of the target TG may be calculated, and the optimal current range for inspecting the target TG may be calculated (S300).

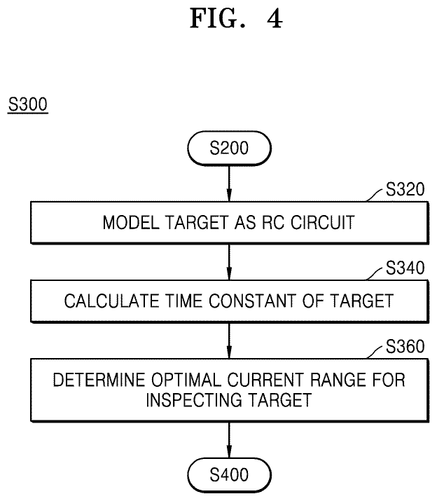

A process of measuring the time constant of the target TG and calculating the optimal current range for inspecting the target TG is described with reference to FIGS. 4 to 8.

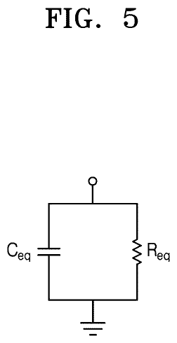

FIG. 4 is a flowchart illustrating a method of calculating a time constant of the target TG and determining the optimal current range for inspecting the target TG according to an example embodiment. FIG. 5 is a diagram illustrating the target TG modeled as a resistor-capacitor (RC) circuit including a resistor and a capacitor according to an example embodiment.

Referring to FIGS. 4 and 5, first, the target TG may be modeled as the RC circuit including the resistor and the capacitor (S320). In an embodiment, each component of the target TG may be converted into and expressed as the resistor and/or the capacitor. In an embodiment, the target TG may be modeled as a circuit with the resistor and the capacitor connected in parallel as shown in FIG. 5. In another embodiment, the target TG may be modeled as a circuit with the resistor and the capacitor connected in series. The target TG may be modeled as the circuit having the resistor and the capacitor, and simply converted into the circuit with the resistor and the capacitor connected in parallel as shown in FIG. 5. That is, the circuit of FIG. 5 may be an equivalent circuit of the circuit of the target TG.

Thereafter, the time constant of the target TG may be calculated (S340). The time constant of the target TG may be calculated based on brightness of a SEM image obtained according to the intensity of a current incident on the target TG. In addition, because the target TG is modeled as the RC circuit, the time constant of a surface voltage of the target TG may be calculated as R_{eq}C_{eq} by multiplying an equivalent resistance value by an equivalent capacitance. The time constant may be a value representing characteristics of the modeled circuit.

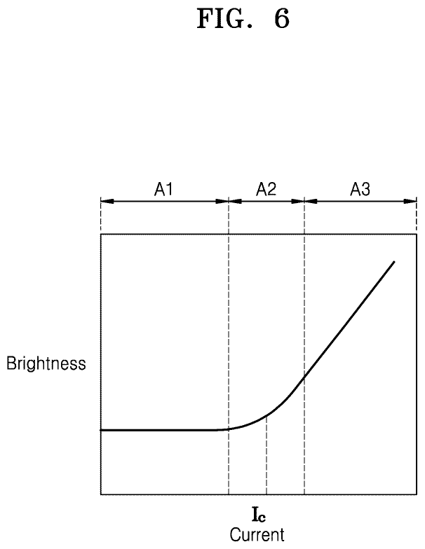

Operation S340 of calculating the time constant of the target TG is described with reference to FIG. 6.

FIG. 6 is a graph illustrating brightness of an obtained SEM image according to an intensity of a current incident on the target TG according to an example embodiment. In FIG. 6, a horizontal axis represents the current incident on the target TG, and a vertical axis represents the intensity of brightness of the SEM image measured by the SEM 100. Each of the horizontal axis and vertical axis is shown in a log scale. In addition, both the horizontal axis and vertical axis are indicated in an arbitrary unit (a.u.).

Referring to FIG. 6, the graph may be divided into three areas. Prior to describing the graph, a critical current is defined for convenience of explanation. The critical current may be a current value at a location where curvature changes significantly in the graph. The critical current may be expressed by Equation 1 below.

$${I}_{c} = \frac{e}{RC} \qquad [ Equation 1 ]$$

Here, I_{c} denotes the critical current, e denotes the amount of charge of electrons, R denotes a resistance value in RC modeling with respect to the semiconductor device SS, and C denotes a capacitance in RC modeling with respect to the semiconductor device SS.

A first area A1 may be an area (Iᵢₙₚᵤₜ<<I_{c}) in which the intensity of a current incident on the target TG is much less than the intensity of the critical current. A second area A2 may be an area (Iᵢₙₚᵤₜ˜I_{c}) in which the intensity of the current incident on the target TG is similar to the intensity of the critical current. A third area A3 may be an area (Iᵢₙₚᵤₜ>>I_{c}) in which the intensity of the current incident on the target TG is much greater than the intensity of the critical current. In example embodiments, the intensity of the current incident on the target TG is similar to the intensity of the critical current when it is within 10% of the critical current (e.g., 0.9(I_{c})≤Iᵢₙₚᵤₜ≤1.1(I_{c})). The intensity of the current incident on the target TG is much greater than the intensity of the critical current when it is greater than 10% of the critical current (e.g., Iᵢₙₚᵤₜ>1.1(I_{c})), and the intensity of the current incident on the target TG is much less than the intensity of the critical current when it is less than 90% of the critical current (e.g., Iᵢₙₚᵤₜ<0.9(I_{c}).

In the first area A1, the brightness of the SEM image may have a small change with respect to a change in current incident on the target TG. In an embodiment, in the first area A1, the intensity of brightness of the SEM image may be expressed as a constant function.

The brightness of the SEM image in the second area A2 may be expressed by Equation 2 below.

$$B ∼ CDF [ \frac{1}{1 - exp ( \frac{- 1}{RC} \frac{e}{{I}_{input}} )} ] \qquad [ Equation 2 ]$$

$$where$$

$$CDF [ x ] = \frac{{x}^{2} ( x + 3 ϕ )}{6 {( x + ϕ )}^{3}}$$

Here, B denotes the brightness of the SEM image, R denotes the resistance value in RC modeling with respect to the semiconductor device SS, C denotes the capacitance in RC modeling with respect to the semiconductor device SS, e denotes the amount of charge of electrons, Iᵢₙₚᵤₜ denotes the intensity of the current incident on the semiconductor device SS, and φ denotes a work function of a surface of the semiconductor device SS.

The brightness of the SEM image in the third area A3 may be expressed by Equation 3 below.

$$B ∼ CDF [ RC \frac{{I}_{input}}{e} ] \qquad [ Equation 3 ]$$

$$where$$

$$CDF [ x ] = \frac{{x}^{2} ( x + 3 ϕ )}{6 {( x + ϕ )}^{3}}$$

Here, B denotes the brightness of the SEM image, R denotes the resistance value in RC modeling with respect to the semiconductor device SS, C denotes the capacitance in RC modeling with respect to the semiconductor device SS, e denotes the amount of charge of electrons, Iᵢₙₚᵤₜ denotes the intensity of the current incident on the semiconductor device SS, and φ denotes the work function of the surface of the semiconductor device SS.

A time constant of the target TG may be calculated based on a relationship between the intensity of the current incident on the target TG and the obtained brightness of the SEM image. In an embodiment, the time constant may be calculated based on a value of the critical current. In Equation 1, the time constant may be calculated based on a value of the critical current and the amount of charges of electrons.

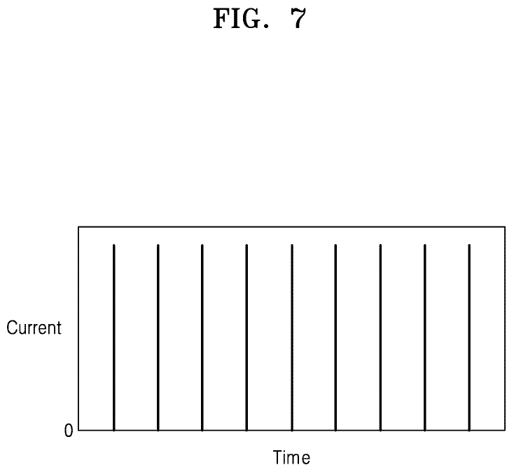

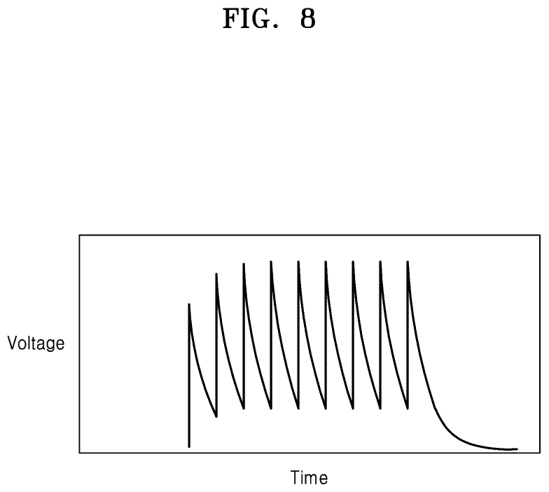

In addition, an impedance of the target TG may be calculated in operation S340. A process of calculating the impedance of the target TG is described in detail with reference to FIGS. 7 and 8.

Referring back to FIG. 4, after the time constant of the target TG is calculated (S340), the optimal current range for inspecting the target TG may be determined (S360). The optimal current range for inspecting the target TG may correspond to an area in which the intensity of the current incident on the target TG is greater than the critical current. For example, the processor 300 may calculate the critical current and select, as the optimal current range, a current range in which the intensity of the current incident on the target TG is much greater than the critical current. For example, a current range in at least a part of the second area A2 and the third area A3 may be included in the area. A change in the brightness of the SEM image may be greater than a change in the intensity of the current incident on the target TG in the area. As described above, on the contrary, in the first area A1, the change in brightness of the SEM image may be small versus the change in intensity of the current incident on the target TG. Therefore, when the current in the range of the first area A1 is incident on the target TG, it may be difficult to measure a difference in the brightness of the SEM image according to the change in the incident current.

Operations S200 and S300 may be performed on a normal target TG. Reference data with respect to operation S400 of inspecting the target TG may be obtained later by performing operations S200 and S300 on the normal target TG. That is, a reference time constant of the target TG and/or the optimal current range for inspecting the target TG may be obtained by performing operations S200 and S300. In addition, data of the brightness of a reference SEM image with respect to the intensity of a specific incident current may be obtained by performing operations S200 and S300.

Hereinafter, a method of calculating the brightness of the SEM image according to the current incident on the target TG in consideration of a quantum mechanical effect of electrons is described. A method of calculating the brightness of the SEM image according to the current incident on the target TG is described with reference to FIGS. 7 and 8.

FIG. 7 is a graph illustrating a current incident on the target TG according to an example embodiment. FIG. 8 is a graph illustrating a surface voltage of the semiconductor device SS generated by the current incident on the target TG according to an example embodiment. In FIG. 7, a horizontal axis represents time, and a vertical axis represents the current incident on the target TG. In FIG. 8, the horizontal axis represents time and the vertical axis represents the surface voltage of the semiconductor device SS. In FIGS. 7 and 8, both the horizontal axis and the vertical axis are indicated in an arbitrary unit (a.u.).

Referring to FIGS. 7 and 8, first, the input electron beam IEB generated from the electron gun 110 may be generated in the form of a discrete electron pulse. That is, the input electron beam IEB generated from the electron gun 110 may include a plurality of temporally separated pulses. In an embodiment, the input electron beam IEB may be treated as an individual electron. That is, the current incident on the target TG may be treated as a discrete electron train and may be analyzed as a movement of individual electrons.

The surface voltage of the target TG may be calculated based on an impedance of the target TG and the intensity of the current applied to the target TG. As the current generated by the SEM 100 is incident on the target TG, the voltage of the surface of the target TG may change. For convenience of description, the input electron beam IEB incident on the target TG may be referred to as a probe current or a first current. When the probe current is applied to the target TG, a second current may be generated from the inside of the target TG to the surface of the target TG. The second current may vary depending on the impedance of the target TG. As the second current is generated, the voltage may change on the surface of the target TG. The number of electrons emitted from the target TG may vary depending on a change in the voltage of the surface of the target TG. The SEM 100 may obtain an SEM image by detecting the emitted electrons.

The surface voltage of the target TG may be calculated based on Equation 4 below.

$${V}_{s} ( t ) ∼ {I}_{input} ( t ) ⊗ Z ( t ) \qquad [ Equation 4 ]$$

Here, Vₛ(t) denotes the surface voltage of the target TG over time, Iᵢₙₚᵤₜ(t) denotes the intensity of the current incident on the target TG over time, and Z(t) denotes the impedance of the target TG over time.

That is, the surface voltage of the target TG may be calculated by convoluting the current applied to the target TG and the impedance of the target TG over time.

According to the quantum mechanical properties of electrons, the surface voltage of the target TG on the graph may include a plurality of independent pulse waves. Considering that the target TG is modeled as an RC circuit, the surface voltage of the target TG may be exponential decay that decreases in proportion to the value of the surface voltage of the target TG over time.

The brightness of the SEM image may be calculated based on the surface voltage of the target TG. The surface voltage of the target TG and the brightness of the SEM image may be proportional to each other. In the graph of FIG. 8, when data of the highest point of each pulse is expressed as the brightness of the SEM image with respect to the current incident on the target TG, the graph of FIG. 6 may be obtained.

As described above, in order to calculate the impedance of the target TG, simulations described with reference to FIGS. 7 and 8 may be performed under various conditions (e.g., various impedances). The impedance of the target TG may be calculated by comparing the current incident on the target TG obtained through simulation and the graph of the brightness of the SEM image with the current incident on the target TG obtained by measurement with the graph of the brightness of the SEM image. In an embodiment, a difference in impedance may be measured based on a separation distance of each graph.

That is, when considering the quantum mechanical effect of electrons, the brightness of the SEM image with respect to the current incident on the target TG may be accurately calculated. Therefore, the reliability of a method of inspecting the semiconductor device SS may increase.

Referring back to FIG. 1, after the time constant of the target TG and the optimal current range for inspecting the target TG are calculated (S300), the target TG may be inspected (S400). As described with reference to FIGS. 4 to 6, a current having the calculated optimal current range may be incident on the target TG to inspect the target TG.

In order to inspect the target TG, the brightness of the SEM image with respect to the current incident on the target TG may be measured. In more detail, the target TG may be inspected by comparing the intensity of the brightness of a first SEM image (reference image) obtained in operations S200 and S300 with the intensity of the brightness of a second SEM image (inspection SEM) obtained in operation S400. As described above, the first SEM image may be an SEM image obtained by measuring the normal target TG. The second SEM image may be an SEM image obtained by measuring the target TG to be inspected. The first SEM image and the second SEM image compared to each other may be images obtained under the same incident current. In an embodiment, when a brightness difference between the first SEM image and the second SEM image is greater than or equal to a threshold value, the target TG may be determined to be defective. On the contrary, in an embodiment, when the difference in the brightness between the first SEM image and the second SEM image is less than or equal to the threshold value, the target TG may be determined to be normal.

From a similar point of view, the semiconductor device SS may be inspected by comparing a first impedance (reference impedance) obtained in operations S200 and S300 with a second impedance (inspection impedance) obtained in operation S400. In an embodiment, when a difference between the first impedance and the second impedance is greater than or equal to a threshold value, the target TG may be determined to be defective. On the contrary, in an embodiment, when the difference between the first impedance and the second impedance is less than or equal to the threshold value, the target TG may be determined to be normal.

In an embodiment, the target TG may be inspected by comparing a first time constant (reference time constant) obtained in operations S200 and S300 with a second time constant (inspection time constant) obtained in operation S400. In an embodiment, when a difference between the first time constant and the second time constant is greater than or equal to a threshold value, the target TG may be determined to be defective. On the contrary, in an embodiment, when the difference between the first time constant and the second time constant is less than or equal to the threshold value, the target TG may be determined to be normal.

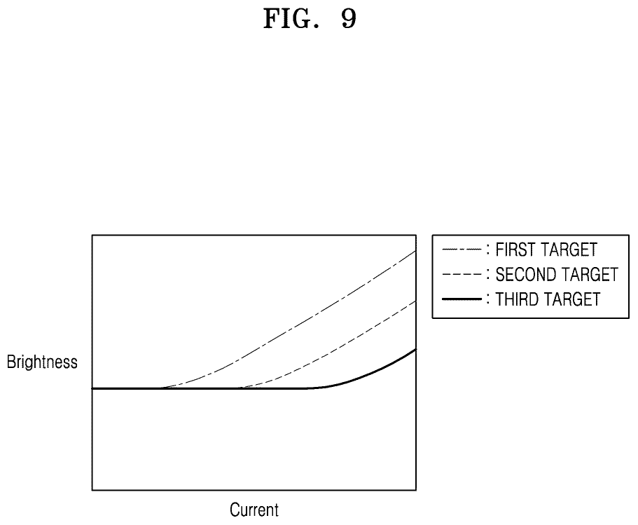

In addition, the target TG may be inspected by comparing graphs of the intensity of brightness of the SEM image according to the incident current. Inspecting the target TG by comparing graphs of the intensity of brightness of the SEM image according to the incident current is described with reference to FIG. 9.

FIG. 9 is a graph illustrating the intensity of brightness of an SEM image according to a current incident on the plurality of targets TG according to an embodiment. In FIG. 9, a horizontal axis represents the intensity of the current incident on the target TG, and a vertical axis represents the intensity of brightness of the SEM image measured by the SEM 100. Each of the horizontal axis and vertical axis is shown in a log scale. In addition, both the horizontal axis and the vertical axis are indicated in an arbitrary unit (a.u.).

Referring to FIG. 9, the intensity of the brightness of the SEM image according to the current incident on the plurality of targets TG is illustrated. In FIG. 9, the plurality of targets TG include a first target, a second target, and a third target. A critical current may be calculated in each of the graphs corresponding to the plurality of targets TG, and the target TG may be inspected based on the critical current. In an embodiment, at least one of the plurality of targets TG may be the normal target TG.

In an embodiment, the target TG may be inspected based on a separation distance of each graph. In an embodiment, a time constant may be calculated in each graph, and the target TG may be inspected based on the time constant. The time constant of the target TG may be calculated based on a relationship between the intensity of the current incident on the target TG and the obtained brightness of the SEM image. In an embodiment, the time constant may be measured based on a value of the critical current. As discussed above, in Equation 1, the time constant may be measured based on a value of the critical current and the amount of charges of electrons. In an embodiment, the critical current may be calculated in each graph, and the target TG may be inspected based on the critical current. The critical current may be a current value at a location where curvature changes significantly in the graph.

The method of inspecting the semiconductor device of the related art performs semiconductor device inspection without considering the quantum mechanical effect of a current. Therefore, the reliability of the semiconductor device inspection is low because a difference between the brightness of a SEM image of a defective semiconductor device and the brightness of a SEM image of a normal semiconductor device is low in an area where the current incident on the semiconductor device is much lower than the critical current. In addition, the method of inspecting the semiconductor device of the related art does not provide a method of calculating an impedance of a semiconductor device and does not provide the optimal current range for inspecting the semiconductor device.

The method of inspecting the semiconductor device SS of the inventive concept may perform an inspection on the target TG by treating the current as a discrete electron train that analyzes the movement of individual electrons. Therefore, the method of inspecting the semiconductor device SS of the inventive concept may accurately describe a relationship between the brightness of the SEM image and the current incident on the target TG. Accordingly, the time constant of the target TG may be easily measured, and the optimal current range for inspecting the target TG may be measured. Therefore, the target TG may be inspected with high reliability.

In more detail, in the graph illustrating the relationship between the intensity of the current incident on the target TG and the obtained brightness of the SEM image, the graph may be divided into a first area where the incident current is much lower than the critical current, a second area where the incident current is similar to the critical current, and a third area where the incident current is much greater than the critical current. The time constant of the target TG may be easily calculated by analyzing a curve of the second area. In addition, whether the target TG is defective may be easily determined by comparing the brightness of a first SEM image with the brightness of a second SEM image at the same input current.

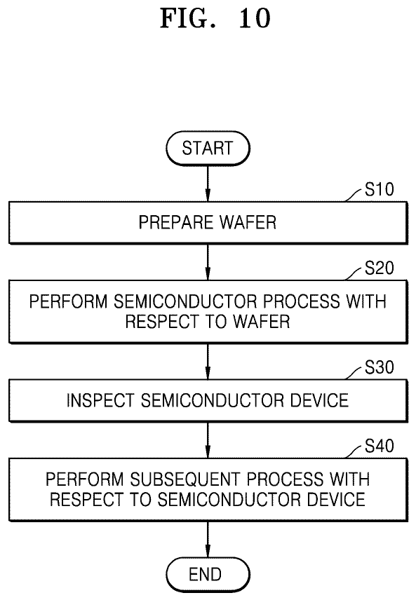

FIG. 10 is a flowchart illustrating a method of manufacturing the semiconductor device SS including a method of inspecting the semiconductor device SS according to an example embodiment. FIG. 10 is described with reference to FIGS. 1 to 9.

Referring to FIG. 10, a wafer may be prepared first (S10). The wafer may include, for example, a bare wafer in which one or more semiconductor processes have been performed or no semiconductor processes have been performed.

Thereafter, a semiconductor process may be performed on the wafer to form the semiconductor device SS (S20). An oxidation process, a photo process, a deposition process, an etching process, an ion process, and/or a cleaning process may be performed on the wafer. In addition, semiconductor processes may include a singulation process of individualizing the wafer into individual semiconductor chips, a test process of testing semiconductor chips, and a packaging process of packaging a semiconductor chip. The semiconductor device SS may be completed through the semiconductor process on the wafer.

Thereafter, the semiconductor device SS may be inspected (S30). Operation S30 of inspecting the semiconductor device SS may include operation S100 of searching for the target TG of the semiconductor device SS of FIG. 1, operation S200 of measuring brightness of an SEM image according to the intensity of a current incident on the target TG, operation S300 of calculating a time constant of the target TG and the optimal current range for inspecting the target TG, and operation S400 of inspecting the target TG to be inspected. In addition, operation S300 of calculating the time constant of the target TG and the optimal current range for inspecting the target TG may include operation S320 of modeling the target TG of FIG. 4 as an RC circuit including a resistor and a capacitor, operation S340 of calculating the time constant of the target TG, and operation S360 of calculating the optimal current range for inspecting the target TG.

Thereafter, a subsequent process on the semiconductor device SS may be performed (S40). When the semiconductor device SS includes the defective target TG, a manufacturing process with respect to the target TG may be modified. For example, modifying the manufacturing process with respect to the target TG may include modifying at least one of material composition, oxygen partial pressure, plasma power, pressure, heat treatment atmosphere, or heat treatment temperature.

While the inventive concept has been particularly shown and described with reference to embodiments thereof, it will be understood that various changes in form and details may be made therein without departing from the spirit and scope of the following claims.

What is claimed is:

1. A method of inspecting a semiconductor device, the method comprising:
searching for a target in the semiconductor device;
obtaining brightness of a scanning electron microscope (SEM) image according to an intensity of a current incident on a normal target;
determining an optimal current range for inspecting the target, based on the brightness of the SEM image according to the intensity of the current; and
inspecting the target, based on a current having the optimal current range,
wherein the determining of the optimal current range for inspecting the target comprises dividing the brightness of the SEM image according to the intensity of the current into a first area, a second area, and a third area, based on the intensity of the current incident on the target,
wherein the first area is an area in which the current incident on the target is much lower than a critical current,
wherein the second area is an area in which the current incident on the target is similar to the critical current,
wherein the third area is an area in which the current incident on the target is much greater than the critical current, and
wherein the critical current is a current corresponding to a point at which curvature of a brightness graph of the SEM image greatly changes according to the intensity of the current.

2. The method of claim 1, wherein the determining of the optimal current range for inspecting the target includes selecting a current corresponding to the third area as the optimal current range.

3. The method of claim 1, further comprising:
calculating a time constant of the target,
wherein the calculating of the time constant of the target is performed based on information of the second area.

4. The method of claim 1, wherein the inspecting of the target, based on the current having the optimal current range, includes comparing a brightness of a first SEM image obtained by inspecting the normal target with a brightness of a second SEM image obtained by inspecting a target to be inspected, under the same current.

5. The method of claim 1, wherein the inspecting of the target, based on the current having the optimal current range, includes comparing graphs of the brightness of the SEM image with respect to a current incident on each of the normal target and a target to be inspected.

6. The method of claim 1, wherein the searching for the target includes at least one of:
searching for the target by pre-scanning the semiconductor device; and
searching for the target based on graphical data with respect to the semiconductor device.

7. The method of claim 1, wherein the determining of the optimal current range for inspecting the target is performed in consideration of a quantum mechanical effect of electrons.

8. A method of inspecting a semiconductor device, the method comprising:
searching for a target in the semiconductor device;
obtaining a brightness of a scanning electron microscope (SEM) image according to an intensity of a current incident on a normal target;
determining a time constant of the target and an optimal current range for inspecting the target, based on the brightness of the SEM image according to the intensity of the current; and
inspecting the target, based on a current having the optimal current range,
wherein the determining of the time constant of the target and the optimal current range for inspecting the target comprises:
modeling the target as a resistor-capacitor (RC) circuit comprising a resistor and a capacitor;
calculating the time constant of the target; and
selecting the optimal current range for inspecting the target, and
wherein the determining of the time constant of the target and the optimal current range for inspecting the target is performed by treating a current incident on the target as a discrete electron train comprising movement of individual electrons.

9. The method of claim 8, wherein the modeling of the target includes modeling the target as an RC circuit with the resistor and the capacitor connected in parallel.

10. The method of claim 8, wherein the calculating of the time constant of the target is performed based on a critical current by selecting the critical current which is a current corresponding to a point at which curvature of a graph changes significantly in the graph of the SEM image according to the intensity of the current incident on the normal target.

11. The method of claim 8, wherein the selecting of the optimal current range for inspecting the target includes selecting a range greater than a critical current which is a current corresponding to a point at which curvature of a graph changes significantly in the graph of the SEM image according to the intensity of the current incident on the normal target.

12. The method of claim 8, wherein the inspecting of the target, based on the current having the optimal current range, includes comparing a first time constant with respect to the normal target and a second time constant with respect to a target to be inspected.

13. The method of claim 8, wherein the determining of the time constant of the target and the optimal current range for inspecting the target includes calculating an impedance of the target.

14. The method of claim 13, wherein the calculating of the impedance of the target includes:
calculating a surface voltage of the target, based on a current incident on the target; and
simulating brightness of an SEM image obtained based on the surface voltage of the target.

15. The method of claim 14, wherein the calculating of the impedance of the target includes comparing a graph of the simulated brightness of the SEM image versus the current incident on the target with a graph of measured brightness of the SEM image versus the current incident on the target.

16. The method of claim 8, wherein the searching for the target in the semiconductor device includes searching for an area where at least a part of a wiring is exposed to an outside.

17. A method of manufacturing a semiconductor device, the method comprising:
preparing a wafer;
manufacturing the semiconductor device by performing a semiconductor process on the wafer;
inspecting the semiconductor device; and
performing a subsequent process with respect to the semiconductor device,
wherein the inspecting of the semiconductor device includes:
searching for a target in the semiconductor device;
obtaining a brightness of a scanning electron microscope (SEM) image according to an intensity of a current incident on the target;
selecting an optimal current range for inspecting the target, based on the brightness of the SEM image according to the intensity of the current; and
inspecting the target, based on a current having the optimal current range,
wherein the selecting of the optimal current range for inspecting the target comprises dividing the brightness of the SEM image according to the intensity of the current into a first area, a second area and a third area, based on the intensity of the current incident on the target,
wherein the first area is an area in which the current incident on the target is much lower than a critical current,
wherein the second area is an area in which the current incident on the target is similar to the critical current,
wherein the third area is an area in which the current incident on the target is much greater than the critical current, and
wherein the critical current is a current corresponding to a point at which curvature of a brightness graph of the SEM image greatly changes according to the intensity of the current.

18. The method of claim 17, further comprising:
calculating a time constant of the target,
wherein the inspecting of the target includes at least one of:
comparing a first time constant of a normal target with a second time constant of a target to be inspected; and
comparing a brightness of a first SEM image of the normal target with a brightness of a second SEM image of the target to be inspected, at the same current.

19. The method of claim 17,
wherein when a difference between a brightness of a first SEM image of a normal target and a brightness of a second SEM image of a target to be inspected is less than or equal to a threshold value, the target to be inspected is determined to be normal, and
wherein when the difference between the brightness of the first SEM image of the normal target and the brightness of the second SEM image of the target to be inspected is greater than or equal to the threshold value, the target to be inspected is determined to be defective.

20. The method of claim 17, wherein the performing of the subsequent process with respect to the semiconductor device includes modifying process conditions with respect to a defective target.
